(19) United States
(12) Patent Application Publication
(10) Pub. No.: US 2025/0233382 A1
(43) Pub. Date: Jul. 17, 2025

(54) LASER DEVICE AND ELECTRONIC DEVICE MANUFACTURING METHOD

(71) Applicant: Gigaphoton Inc., Tochigi (JP)

(72) Inventors: Takamitsu KOMAKI, Oyama-shi (JP); Toshihiro OGA, Oyama-shi (JP); Takehiko TOMONAGA, Oyama-shi (JP); Takahito KUMAZAKI, Oyama-shi (JP)

(73) Assignee: Gigaphoton Inc., Tochigi (JP)

(21) Appl. No.: 19/171,840

(22) Filed: Apr. 7, 2025

Related U.S. Application Data
(63) Continuation of application No. PCT/JP2022/044029, filed on Nov. 29, 2022.

(51) Int. Cl. H01S 3/13; G01J 1/04; G01J 1/42; G03F 7/00; H01S 3/136

(52) U.S. Cl. CPC H01S 3/1305; G01J 1/0474; G01J 1/4257; G03F 7/70025; G03F 7/70041; G03F 7/70575; G03F 7/70583; H01S 3/136

(57) ABSTRACT

A laser device includes a laser oscillation device configured to output pulse laser light; a beam intensity distribution measurement device configured to measure a beam intensity distribution of the pulse laser light; a beam angle distribution measurement device configured to measure a beam angle distribution of the pulse laser light; a pulse waveform measurement device configured to measure a pulse waveform of the pulse laser light; a spectrum measurement device configured to measure a spectrum of the pulse laser light; and a laser controller configured to calculate a speckle contrast based on measurement data of each of the beam intensity distribution, the beam angle distribution, the pulse waveform, and the spectrum.

### CROSS-REFERENCE TO RELATED APPLICATIONS

The present application claims the benefit of International Application No. PCT/JP2022/044029, filed on Nov. 29, 2022, the entire contents of which are hereby incorporated by reference.

### BACKGROUND

### 1. Technical Field

The present disclosure relates to a laser device and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as the gas laser device for exposure, a KrF excimer laser device that outputs laser light having a wavelength of about 248 nm and an ArF excimer laser device that outputs laser light having a wavelength of about 193.4 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line- narrow a spectral line width. A gas laser device with a narrowed spectral line width is referred to as a line narrowing gas laser device.

### LIST OF DOCUMENTS

### Patent Documents

Patent Document 1: U.S. Pat. No. 9,945,730

Patent Document 2: International Publication No. WO2007/053335

Patent Document 3: US Patent Application Publication No. 2020/0060557

### SUMMARY

A laser device according to an aspect of the present disclosure includes a laser oscillation device configured to output pulse laser light; a beam intensity distribution measurement device configured to measure a beam intensity distribution of the pulse laser light; a beam angle distribution measurement device configured to measure a beam angle distribution of the pulse laser light; a pulse waveform measurement device configured to measure a pulse waveform of the pulse laser light; a spectrum measurement device configured to measure a spectrum of the pulse laser light; and a laser controller configured to calculate a speckle contrast based on measurement data of each of the beam intensity distribution, the beam angle distribution, the pulse waveform, and the spectrum.

An electronic device manufacturing method according to an aspect of the present disclosure includes outputting pulse laser light from a laser device to an exposure apparatus, and exposing a photosensitive substrate to the pulse laser light in the exposure apparatus to manufacture an electronic device. Here, the laser device includes a laser oscillation device configured to output the pulse laser light; a beam intensity distribution measurement device configured to measure a beam intensity distribution of the pulse laser light; a beam angle distribution measurement device configured to measure a beam angle distribution of the pulse laser light; a pulse waveform measurement device configured to measure a pulse waveform of the pulse laser light; a spectrum measurement device configured to measure a spectrum of the pulse laser light; and a laser controller configured to calculate a speckle contrast based on measurement data of each of the beam intensity distribution, the beam angle distribution, the pulse waveform, and the spectrum.

### BRIEF DESCRIPTION OF THE DRAWINGS

Embodiments of the present disclosure will be described below merely as examples with reference to the accompanying drawings.

FIG. 1 shows an example of a speckle image.

FIG. 2 is a diagram schematically showing an intensity distribution of the speckle image.

FIG. 3 is a diagram showing an outline of FWHM as an example of a spectral line width.

FIG. 4 is a diagram showing an outline of E95 as an example of the spectral line width.

FIG. 5 is a view schematically showing the configuration of a laser device according to a comparative example.

FIG. 6 is a view for explaining a problem of the laser device according to the comparative example.

FIG. 7 is a view schematically showing the configuration of the laser device according to a first embodiment.

FIG. 8 is a view schematically showing the configuration of a beam measurement device.

FIG. 9 is a view schematically showing the configuration of a spectrum measurement device.

FIG. 10 is a diagram showing an example of interference fringes.

FIG. 11 is a view schematically showing the configuration of the laser device according to a second embodiment.

FIG. 12 is a diagram schematically showing the configuration of a gas control device.

FIG. 13 is a diagram showing an example of the relationship between a pulse width and a pressure of an F₂ gas in a chamber.

FIG. 14 is a flowchart schematically showing a flow of control of a SC.

FIG. 15 is a view schematically showing the configuration of the laser device according to a modification of the second embodiment.

FIG. 16 is a view schematically showing the configuration of a wavefront changing device.

FIG. 17 is a flowchart schematically showing a flow of control of the SC according to the modification of the second embodiment.

FIG. 18 is a view schematically showing the configuration of the laser device according to a third embodiment.

FIG. 19 is a view schematically showing the configuration of an OPS according to the third embodiment.

FIG. 20 is a diagram showing an example of the relationship between the SC and the spectral line width.

FIG. 21 is a diagram showing an adjustment example of control parameters of the SC.

FIG. 22 is a flowchart schematically showing a flow of control of the SC according to the third embodiment.

FIG. 23 is a flowchart schematically showing a flow of control of the SC according to the third embodiment.

FIG. 24 is a view schematically showing the configuration of a pulse width changing device according to a first modification.

FIG. 25 is a view schematically showing the configuration of a reflectance-variable beam splitter device.

FIG. 26 is a diagram showing an example of pulse waveforms before and after extension by the OPS.

FIG. 27 is a diagram showing an example of the relationship between a reflectance of the beam splitter and the pulse width.

FIG. 28 is a view schematically showing the configuration of the pulse width changing device according to a second modification.

FIG. 29 is a view schematically showing the configuration of the pulse width changing device according to a third modification.

FIG. 30 is a diagram showing an example of the relationship between the pulse width and a pressure of an Ar gas in the chamber.

FIG. 31 schematically shows the configuration of an etendue changing device according to a first modification.

FIG. 32 is a front view schematically showing the configuration of the etendue changing device according to a second modification.

FIG. 33 is a side view schematically showing the configuration of the etendue changing device according to the second modification.

FIG. 34 is a diagram showing an example of changing a beam angle distribution.

FIG. 35 is a side view schematically showing the configuration of the etendue changing device in a case of adjusting a beam intensity distribution.

FIG. 36 is a diagram showing an example of changing the beam intensity distribution.

FIG. 37 is a front view schematically showing the configuration of the etendue changing device according to a third modification.

FIG. 38 is a side view schematically showing the configuration of the etendue changing device according to the third modification.

FIG. 39 is a view for explaining operation of changing a slit width.

FIG. 40 is a front view schematically showing the configuration of the etendue changing device according to a fourth modification.

FIG. 41 is a side view schematically showing the configuration of the etendue changing device according to a fifth modification.

FIG. 42 is a view showing an example of the beam angle distribution and the beam intensity distribution on each of an output plane, a Fourier transform plane, and a conjugate plane.

FIG. 43 is a diagram showing an adjustment example of the beam angle distribution and the beam intensity distribution by a first variable slit device and a second variable slit device.

FIG. 44 is a view schematically showing the configuration of a spectral line width changing device according to a modification.

FIG. 45 is a view for explaining operation of the spectral line width changing device. FIG. 46 is a view showing an example in which the spectral line width is changed through combination of a line narrowing device and the wavefront changing device.

FIG. 47 is a diagram schematically showing a configuration example of an exposure apparatus.

### DESCRIPTION OF EMBODIMENTS

### Contents

### 1. Description of Terms

1.1 Speckle contrast
1.2 Pulse width
1.3 Spectral line width
1.4 Temporal coherence length
1.5 Etendue

### 2. Comparative Example

2.1 Configuration
2.2 Operation
2.3 Problem

### 3. First Embodiment

3.1 Overall configuration
3.2 Beam measurement device
3.3 Spectrum measurement device
3.4 Operation
3.5 Effect

### 4. Second Embodiment

4.1 Overall configuration
4.2 Gas control device
4.3 Operation
4.4 Effect
4.5 Modification

### 5. Third Embodiment

5.1 Overall configuration
5.2 OPS
5.3 Operation
   5.3.1 Adjustment example of control parameter of SC
   5.3.2 Control flow of SC
5.4 Effect

### 6. Modification of Pulse Width Changing Device

6.1 First modification
6.2 Second modification
6.3 Third modification

### 7. Modification of Etendue Changing Device

7.1 First modification
7.2 Second modification
7.3 Third modification
7.4 Fourth modification
7.5 Fifth modification

### 8. Modification of Spectral Line Width Changing Device

### 9. Electronic Device Manufacturing Method

### 10. Configuration Example of Laser Controller

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Terms

### 1.1 Speckle Contrast

Speckle is light and dark spots caused when laser light is scattered in a random medium. A speckle contrast (SC) is generally used as a speckle evaluation index. The SC is represented by the following expression (1). Here, σ is a standard deviation calculated based on the intensity distribution of a speckle image. Iₐ is an average intensity of the intensity distribution of the speckle image.

$$[ Expression 1 ]$$

$$SC = \frac{σ}{{I}_{a}} \qquad ( 1 )$$

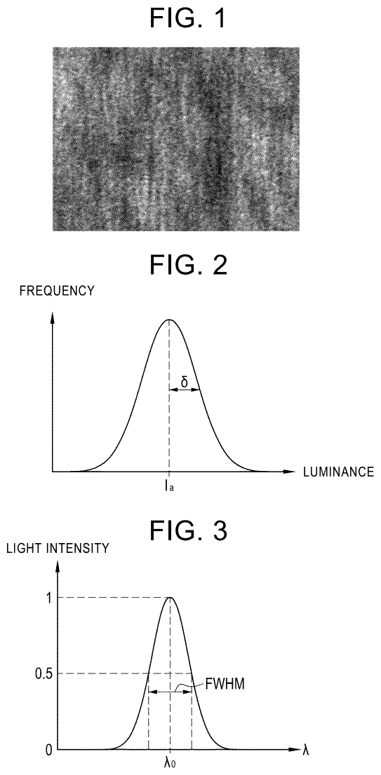

For example, when the SC of laser light representing the speckle image as shown in FIG. 1 is calculated, the intensity distribution is created by converting the intensity of each pixel of the image into a histogram as shown in FIG. 2. The standard deviation σ and the average intensity Iₐ are calculated based on the intensity distribution, and applied to the above expression (1) to calculate the SC.

### 1.2 Pulse Width

In the present disclosure, a pulse width W of the laser light is defined by time-integral square (TIS) represented by the following expression (2). Here, I(t) represents the light intensity for each time t in a pulse waveform.

$$[ Expression 2 ]$$

$$TIS = \frac{{( \int I ( t ) dt )}^{2}}{\int {I ( t )}^{2} dt} \qquad ( 2 )$$

### 1.3 Spectral Line Width

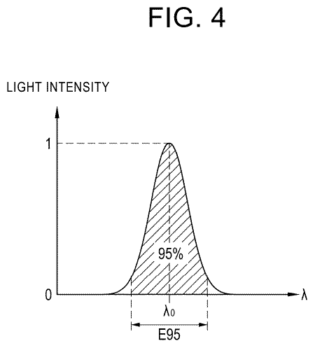

FIG. 3 shows an outline of full width at half maximum (FWHM) as an example of the spectral line width. FIG. 4 shows an outline of E95 as an example of the spectral line width. In FIGS. 3 and 4, the horizontal axis represents a wavelength λ, and the vertical axis represents the light intensity. The spectral line width is the total width of the spectral waveform of the laser light at a light amount threshold. In the present disclosure, a relative value of each respective light amount threshold with respect to the light amount peak value is referred to as a line width threshold Thresh (0<Thresh<1).

As shown in FIG. 3, the full width of the spectral waveform at Thresh=0.5 is referred to as FWHM.

Further, in the present disclosure, as shown in FIG. 4, the full width of the spectral waveform of a portion that occupies 95% of the total spectral energy around a center wavelength λ₀ is referred to as spectral purity. The spectral line width Δλ that becomes the spectral purity is referred to as E95. Regarding the spectral purity, when the spectral waveform is g(λ), the following expression (3) is satisfied.

$$[ Expression 3 ]$$

$$\frac{{\int }_{- Δλ / 2}^{Δλ / 2} g ( λ + {λ}_{0} ) d λ}{{\int }_{- ∞}^{∞} g ( λ + {λ}_{0} ) d λ} = 0.95 \qquad ( 3 )$$

### 1.4 Temporal Coherence Length

In the present disclosure, a temporal coherence length C_{L} is defined by the following expression (4) using the center wavelength λ₀ of the laser light and the spectral line width Δλ.

$$[ Expression 4 ]$$

$${C}_{L} = \frac{{λ}_{0}^{2}}{Δ λ} \qquad ( 4 )$$

### 1.5 Etendue

In the present disclosure, an etendue ET is defined by the following expression (5) using a beam cross-sectional area A and a beam divergence angle Ω. That is, the etendue ET is the product of the beam cross-sectional area A and the beam divergence angle Ω.

$$[ Expression 5 ]$$

$$ET = A \cdot Ω \qquad ( 5 )$$

The beam divergence angle Ω is defined as the solid angle expressed as the area of a part cut out by a pyramid surface from a sphere of radius 1 centered on the apex of the angle. The beam divergence angle Ω is expressed by the following expression (6) using a numerical aperture NA and the circumferential ratio π.

$$[ Expression 6 ]$$

$$Ω = π \cdot {NA}^{2} \qquad ( 6 )$$

### 2. Comparative Example

First, a comparative example of the present disclosure will be described. The comparative example of the present disclosure is an example recognized by the applicant as known only by the applicant, and is not a publicly known example admitted by the applicant.

### 2.1 Configuration

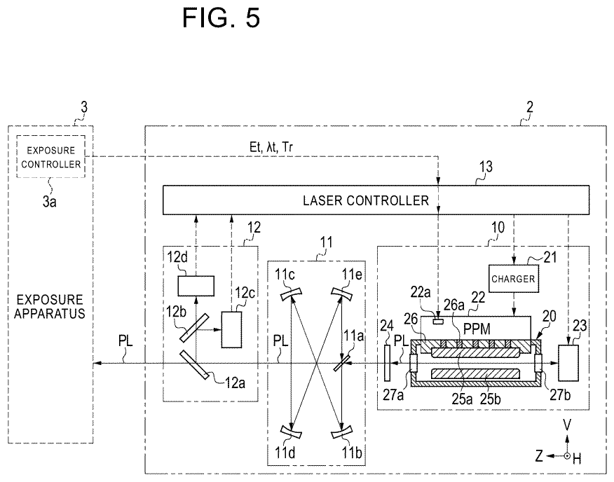

FIG. 5 schematically shows the configuration of a laser device 2 according to the comparative example. The laser device 2 includes an oscillation device 10, an optical pulse stretcher (OPS) 11, a monitor module 12, and a laser controller 13. The OPS 11 and the monitor module 12 are arranged in this order on the optical path of pulse laser light PL output from the oscillation device 10. The laser device 2 is an excimer laser device for outputting pulse laser light PL that enters an exposure apparatus 3.

In the present embodiment, the optical path axis direction of the pulse laser light PL is defined as a Z direction. Two directions substantially orthogonal to the Z direction are defined as an H direction and a V direction. The H direction is a direction substantially orthogonal to the paper surface of FIG. 5.

The oscillation device 10 includes a chamber 20, a charger 21, a pulse power module (PPM) 22, a line narrowing device 23, and an output coupling mirror 24. The line narrowing device 23 and the output coupling mirror 24 configure an optical resonator, and the chamber 20 is arranged on the optical path of the optical resonator.

The chamber 20 includes a pair of electrodes 25a, 25b, an insulating member 26, a front-side window 27a, and a rear-side window 27b. A laser gas is enclosed in the chamber 20. The laser gas may include, for example, an Ar gas, a Kr gas, or an Xe gas as an inert gas, an F₂ gas or a Cl₂ gas as a halogen gas, and an Ne gas as a buffer gas. The pair of electrodes 25a, 25b are arranged in the chamber 20 as electrodes for exciting the laser gas by discharge. The pair of electrodes 25a, 25b extend in the Z direction and face each other with a predetermined gap distance maintained in the V direction. The discharge direction of the pair of electrodes 25a, 25b is the V direction.

An opening is formed in the chamber 20, and the opening is closed by the insulating member 26. A plurality of conductive portions 26a are embedded in the insulating member 26. The electrode 25a is connected to the PPM 22 via the plurality of conductive portions 26a. The electrode 25b is connected to the ground. The plurality of conductive portions 26a apply a high voltage supplied from the PPM 22 to the electrode 25a.

The front-side window 27a and the rear-side window 27b are arranged at both ends of the chamber 20 so that the pulse laser light PL generated in a discharge space between the pair of electrodes 25a, 25b is transmitted.

The PPM 22 includes a switch 22a. The switch 22a is controlled by the laser controller 13. The charger 21 is connected to a charging capacitor of the PPM 22. The charger 21 receives charging voltage data from the laser controller 13.

The line narrowing device 23 includes a prism (not shown), a grating (not shown), and an actuator (not shown). The actuator is controlled by the laser controller 13 to change the angle of the prism or grating.

The OPS 11 includes a beam splitter 11a and concave mirrors 11b to 11e. The beam splitter 11a is arranged on the optical path of the pulse laser light PL output from the oscillation device 10, and a film that reflects a part of the pulse laser light PL and transmits another part is formed thereon. Preferably, the reflectance of the beam splitter 11a is about 60%.

Each of the concave mirrors 11b to 11e has a focal length of f being approximately equal to each other. The concave mirrors 11b to 11e are arranged such that the pulse laser light PL reflected by the beam splitter 11a is imaged with the image thereof being inverted by the concave mirrors 11b, 11c, and further, imaged with the image thereof being inverted by the concave mirrors 11d, 11e. An erect image is formed on the beam splitter 11a via the concave mirrors 11b to 11e. The concave mirrors 11b to 11e configure a delay optical path. When the delay optical path length is L, it is preferable that L=8f. Here, the delay optical path length L is set to be longer than the temporal coherence length C_{L} of the pulse laser light PL.

The monitor module 12 includes beam splitters 12a, 12b, a pulse energy measurement device 12c, and a spectrum measurement device 12d. The beam splitter 12a is arranged on the optical path of the pulse laser light PL output from the OPS 11, and a film that reflects a part of the pulse laser light PL and transmits another part is formed thereon. The beam splitter 12b is arranged on the optical path of the pulse laser light PL reflected by the beam splitter 12a, and a film that reflects a part of the pulse laser light PL and transmits another part is formed thereon. The pulse laser light PL transmitted through the beam splitter 12a enters the exposure apparatus 3.

The pulse energy measurement device 12c is arranged on the optical path of the pulse laser light PL reflected by the beam splitter 12b, and measures the pulse energy of the pulse laser light PL. The spectrum measurement device 12d is arranged on the optical path of the pulse laser light PL transmitted through the beam splitter 12b, and measures the spectrum of the pulse laser light PL. The measurement data of the pulse energy and the measurement data of the spectrum are transmitted to the laser controller 13.

The laser controller 13 is connected to an exposure controller 3a of the exposure apparatus 3 via a signal line. The laser controller 13 receives a signal from the exposure controller 3a. The signal received by the laser controller 13 includes a target pulse energy Et, a target wavelength λt, and a light emission trigger Tr.

An amplifier configured including a chamber similar to the chamber 20 may be arranged between the oscillation device 10 and the OPS 11.

The exposure apparatus 3 is an apparatus that performs exposure using the pulse laser light PL. The exposure apparatus 3 includes a scanner that performs step-and-scan exposure. The step-and-scan exposure is a method of exposing a reticle and a photosensitive substrate such as a semiconductor wafer in conjunction with each other. In the scanner, exposure is performed by the pulse laser light PL while scanning an elongated slit-shaped region.

### 2.2 Operation

Next, operation of the laser device 2 according to the comparative example will be described. First, the laser controller 13 receives the target pulse energy Et, the target wavelength At, and the light emission trigger Tr from the exposure controller 3a. The light emission trigger Tr is transmitted from the exposure controller 3a to the laser controller 13 at a predetermined repetition frequency.

The laser controller 13 turns on the switch 22a of the PPM 22 in synchronization with the light emission trigger Tr. When the switch 22a is turned on, a high voltage is applied from the PPM 22 to the pair of electrodes 25a, 25b. Accordingly, discharge occurs between the pair of electrodes 25a, 25b, and the laser gas is excited. As a result, laser oscillation occurs at the optical resonator, and the pulse laser light PL line-narrowed by the line narrowing device 23 is output from the output coupling mirror 24.

The pulse laser light PL output from the oscillation device 10 enters the OPS 11. A part of the pulse laser light PL entering the OPS 11 is reflected by the beam splitter 11a, and the light that has circulated through the delay optical path by one or more times is superimposed on the pulse laser light PL, whereby the pulse width W is extended.

The pulse laser light PL whose pulse width W is extended by the OPS 11 enters the monitor module 12. A part of the pulse laser light PL entering the monitor module 12 is reflected by the beam splitter 12a. A part of the pulse laser light PL reflected by the beam splitter 12a is reflected by the beam splitter 12b and enters the pulse energy measurement device 12c, so that the pulse energy is measured. Further, the other part of the pulse laser light PL reflected by the beam splitter 12a is transmitted through the beam splitter 12b and enters the spectrum measurement device 12d, so that the spectrum is measured.

The laser controller 13 controls the charge voltage of the charger 21 so that the difference between the target pulse energy Et and the measured pulse energy approaches zero. Further, the laser controller 13 calculates the center wavelength λ₀ from the measured spectrum, and controls the actuator of the line narrowing device 23 so that the difference between the target wavelength λt and the center wavelength λ₀ approaches zero.

As described above, the laser controller 13 turns on the switch 22a in synchronization with the light emission trigger Tr, whereby the pulse laser light PL is output from the laser device 2. The pulse laser light PL output from the laser device 2 has the extended pulse width W, a pulse energy close to the target pulse energy Et, and the center wavelength λ₀ close to the target wavelength At.

The pulse laser light PL output from the laser device 2 enters the exposure apparatus 3 and is radiated to a photosensitive substrate such as a semiconductor wafer (not shown).

### 2.3 Problem

In the wafer exposure, it is required to reduce the SC caused by coherence of the pulse laser light PL. In the laser device 2, in order to reduce the SC by reducing the coherence of the pulse laser light PL, the pulse width W is extended by the OPS 11.

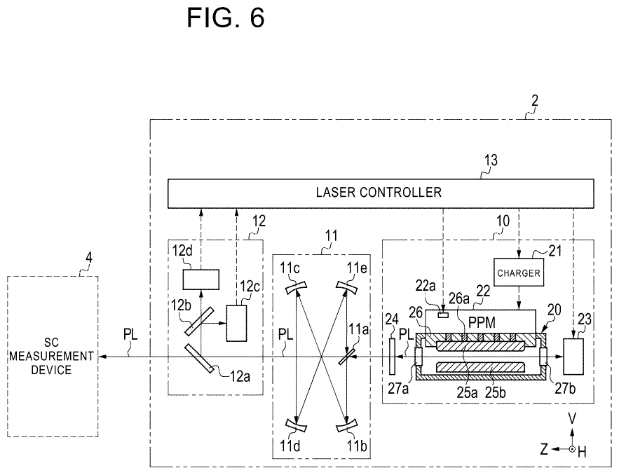

In a performance check before shipment, it is checked whether or not the laser device 2 satisfies the required performance of the SC required by the exposure apparatus 3. As shown in FIG. 6, in order to check the SC caused by the pulse laser light PL output from the laser device 2, an SC measurement device 4 is installed near the emission port of the laser device 2. The SC measurement device 4 measures the SC by calculating a standard deviation σ and an average intensity la based on an intensity distribution of the speckle image.

However, since the laser device 2 has a large volume, it is difficult to disconnect the exposure apparatus 3 and connect the SC measurement device 4 again after the exposure apparatus 3 is connected to the laser device 2. Therefore, after the exposure apparatus 3 is connected to the laser device 2, the SC is hardly measured. Therefore, even if the SC is deteriorated due to some failure or deterioration over time of the laser device 2, the SC cannot be directly detected, and therefore deterioration of the SC must be estimated using deterioration of other parameters. Further, even if the failure of the laser device 2 is solved, whether the SC is improved or not must be determined also by estimation.

As described above, there is a demand for a technology capable of detecting deterioration of the SC in a state in which the exposure apparatus 3 is connected to the laser device 2.

### 3. First Embodiment

Next, the laser device 2 according to a first embodiment of the present disclosure will be described. Hereinafter, the same components are denoted by the same numeral, and description thereof is appropriately omitted.

### 3.1 Overall Configuration

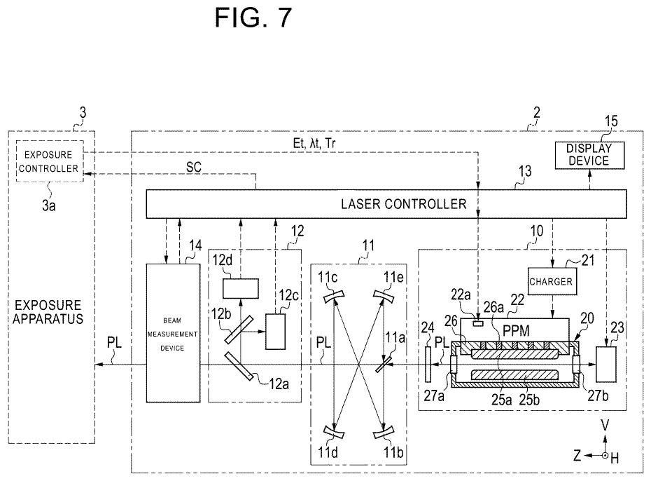

FIG. 7 schematically shows the configuration of the laser device 2 according to the first embodiment. The laser device 2 according to the present embodiment includes a beam measurement device 14 and a display device 15 in addition to the oscillation device 10, the OPS 11, the monitor module 12, and the laser controller 13.

The beam measurement device 14 is arranged in a stage subsequent to the monitor module 12. The beam measurement device 14 measures the beam intensity distribution, the beam angle distribution, and the pulse waveform of the pulse laser light PL having passed through the monitor module 12, and transmits measurement data to the laser controller 13. The beam measurement device 14 may be arranged between the OPS 11 and the monitor module 12.

In the present embodiment, the laser controller 13 calculates the etendue ET from the beam intensity distribution and the beam angle distribution measured by the beam measurement device 14, and calculates the pulse width W from the pulse waveform measured by the beam measurement device 14. Specifically, the laser controller 13 calculates the beam cross-sectional area A of the pulse laser light PL from the beam intensity distribution, calculates the beam divergence angle Ω of the pulse laser light PL from the beam angle distribution, and calculates the etendue ET by multiplying the beam cross-sectional area A by the beam divergence angle Ω.

Further, the laser controller 13 calculates the spectral line width AX from the spectrum measured by the spectrum measurement device 12d of the monitor module 12.

Further, the laser controller 13 uses the calculated etendue ET, spectral line width Δλ, and pulse width W to calculate the SC by the following expression (7). Expression (7) below means that the SC is proportional to the square root of the sum of a spatial SC and a temporal SC.

$$[ Expression 7 ]$$

$$SC = \sqrt{\frac{1}{{N}_{pulse}}} \times \sqrt{\frac{1}{W} \cdot \frac{{λ}^{2}}{c \cdot Δλ} + \frac{{λ}^{2}}{ET}} \qquad ( 7 )$$

Here, Nₚᵤₗₛₑ is the number of pulses of the pulse laser light PL to be used by the exposure apparatus 3 at the time of exposure. c is the speed of light. λ is the wavelength of the pulse laser light PL. In the present embodiment, the target wavelength λt received from the exposure apparatus 3 is set as the wavelength λ of the above expression (7). Here, the laser controller 13 may set the center wavelength λ₀ calculated based on the spectrum measured by the spectrum measurement device 12d as the wavelength λ of the above expression (7).

In the present embodiment, the pulse width W is defined as TIS, and the spectral line width Δλ is defined as E95. Hereinafter, the pulse width W is referred to as a pulse width TIS, and the spectral line width Δλ is referred to as a spectral line width E95.

The laser controller 13 acquires the pulse number Nₚᵤₗₛₑ from the exposure apparatus 3, and calculates the SC using the acquired pulse number Nₚᵤₗₛₑ. Here, the laser controller 13 may calculate the SC using a fixed value of the pulse number Nₚᵤₗₛₑ stored in advance without acquiring the pulse number Nₚᵤₗₛₑ from the exposure apparatus 3. The fixed value of the number of pulses Nₚᵤₗₛₑ is, for example, 40.

For example, the laser controller 13 calculates the etendue ET, the spectral line width E95, and the pulse width TIS for each pulse of the pulse laser light PL. Alternatively, the laser controller 13 may calculate, for the etendue ET, the spectral line width E95, and the pulse width TIS, the average value of the number of pulses Nₚᵤₗₛₑ used for exposure at one position by the exposure apparatus 3.

The display device 15 is a liquid crystal display or the like, and displays the SC calculated by the laser controller 13 based on the control of the laser controller 13. Further, the laser controller 13 transmits the calculated SC to the exposure apparatus 3.

### 3.2 Beam Measurement Device

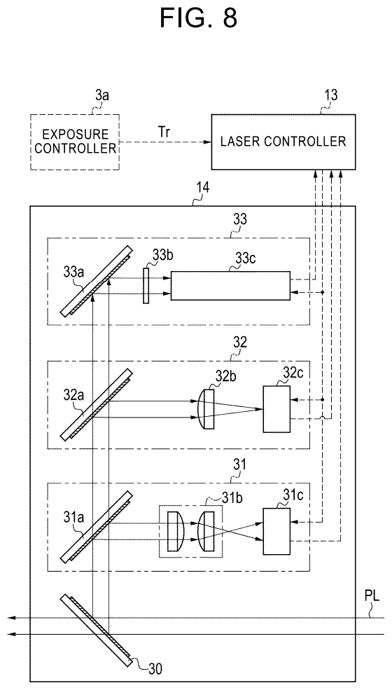

FIG. 8 schematically shows the configuration of the beam measurement device 14. The beam measurement device 14 includes a beam splitter 30, a beam intensity distribution measurement device 31, a beam angle distribution measurement device 32, and a pulse waveform measurement device 33.

The beam splitter 30 is arranged on the optical path of the pulse laser light PL, and reflects a part of the pulse laser light PL and transmits the other part thereof. A multilayer film having the same reflectance for p-polarized light and s-polarized light may be formed on one surface of the beam splitter 30, and an anti-reflection film may be formed on the other surface.

The beam intensity distribution measurement device 31 includes a beam splitter 31a, a transfer optical system 31b, and an image sensor 31c. The beam splitter 31a is arranged on the optical path of the pulse laser light PL reflected by the beam splitter 30, and reflects a part of the pulse laser light PL and transmits the other part thereof. A multilayer film having the same reflectance for p-polarized light and s-polarized light may be formed on one surface of the beam splitter 31a, and an anti-reflection film may be formed on the other surface.

The transfer optical system 31b includes a plurality of lenses and is arranged on the optical path of the pulse laser light PL reflected by the beam splitter 31a. The transfer optical system 31b transfers the beam cross-sectional image of the pulse laser light PL to the image sensor 31c.

The image sensor 31c is an imaging element such as a two-dimensional charge-coupled device (CCD), and is arranged such that an imaging surface thereof is positioned at a position of an image transferred by the transfer optical system 31b. The image sensor 31c generates image data by capturing an image of the pulse laser light PL transferred to the imaging surface, and outputs the image data to the laser controller 13. The image data corresponds to measurement data of the beam intensity distribution.

The beam angle distribution measurement device 32 includes a beam splitter 32a, a light concentrating optical system 32b, and an image sensor 32c. The beam splitter 32a is arranged on the optical path of the pulse laser light PL transmitted through the beam splitter 30, and reflects a part of the pulse laser light PL and transmits the other part thereof. A multilayer film having the same reflectance for p-polarized light and s-polarized light may be formed on one surface of the beam splitter 32a, and an anti-reflection film may be formed on the other surface thereof.

The light concentrating optical system 32b includes a lens and is arranged on the optical path of the pulse laser light PL reflected by the beam splitter 32a. The light concentrating optical system 32b concentrates the pulse laser light PL on the image sensor 32c.

The image sensor 32c is a two-dimensional imaging element such as a CCD, and is arranged such that an imaging surface thereof is positioned at a position of an image concentrated by the light concentrating optical system 32b. The image sensor 32c generates image data by capturing an image of the pulse laser light PL concentrated on the imaging surface, and outputs the image data to the laser controller 13. The image data corresponds to measurement data of the beam angle distribution. Therefore, the beam angle distribution to be measured by the beam angle distribution measurement device 32 may be a concentrated image of the pulse laser light PL.

The pulse waveform measurement device 33 includes a high reflection mirror 33a, a diffusion plate 33b, and a biplanar photoelectric tube 33c. The high reflection mirror 33a is arranged on the optical path of the pulse laser light PL transmitted through the beam splitter 32a, and highly reflects the pulse laser light PL. A total reflection film may be formed on the high reflection mirror 33a.

The diffusion plate 33b is arranged on the optical path of the pulse laser light PL reflected by the high reflection mirror 33a, and transmits and diffuses the pulse laser light PL.

The biplanar photoelectric tube 33c is arranged at a position where the pulse laser light PL diffused by the diffusion plate 33b can be received. The biplanar photoelectric tube 33c measures the pulse waveform of the pulse laser light PL, and outputs data of the measured pulse waveform to the laser controller 13.

The laser controller 13 is connected to the image sensors 31c, 32c and the biplanar photoelectric tube 33c. Operation of the image sensors 31c, 32c and the biplanar photoelectric tube 33c is controlled by the laser controller 13.

Based on the image data output from the image sensor 31c, the laser controller 13 calculates the beam cross-sectional area A using a value obtained by dividing the square of the sum of the intensities of the pixels by the sum of the squares of the intensities of the pixels as an index. Further, based on the image data output from the image sensor 32c, the laser controller 13 calculates the beam divergence angle 22 using a value obtained by dividing the square of the sum of the intensities of the pixels by the sum of the squares of the intensities of the pixels as an index.

### 3.3 Spectrum Measurement Device

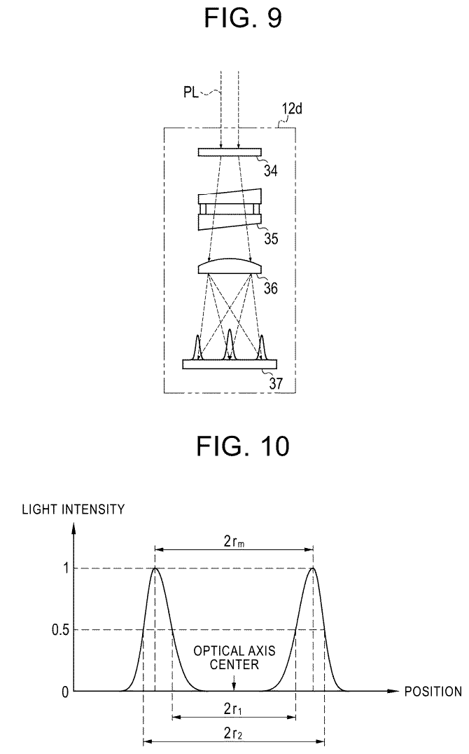

FIG. 9 schematically shows the configuration of the spectrum measurement device 12d. In the present embodiment, an etalon spectrometer is used as the spectrum measurement device 12d. The spectrum measurement device 12d includes a diffusion plate 34, an etalon 35, a light concentrating lens 36, and an image sensor 37.

The diffusion plate 34 transmits and diffuses the pulse laser light PL having entered the spectrum measurement device 12d. The pulse laser light PL diffused by the diffusion plate 34 enters the etalon 35 and then is incident on the light concentrating lens 36. The pulse laser light PL generates interference fringes on the focal plane of the light concentrating lens 36.

The image sensor 37 is arranged at the focal plane of the light concentrating lens 36, and generates image data by capturing the interference fringes and outputs the image data to the laser controller 13. The image data corresponds to measurement data of the spectrum.

The square of a radius rₘ of an interference fringe is proportional to the wavelength A of the pulse laser light PL. Therefore, the laser controller 13 can calculate the spectral line width E95 and the center wavelength λ₀ based on the image data output from the image sensor 37. The relationship between the radius rₘ of the interference fringe and the wavelength λ is approximated by the following expression (8).

$$[ Expression 8 ]$$

$$λ = {λ}_{c} + α \cdot {r}_{m}^{2} \qquad ( 8 )$$

Here, λ_{c} is the wavelength at which the light intensity at the center of the interference fringes becomes maximum. α is a proportional constant. The spectral waveform representing the relationship between the light intensity and the wavelength λ can be calculated by the above expression (8).

FIG. 10 shows an example of the interference fringes. The square of the radius rₘ of the interference fringes can be calculated using the following expression (9) by measuring an inner radius r₁ and an outer radius r₂ of half values of the light intensity.

$$[ Expression 9 ]$$

$${r}_{m}^{2} = \frac{{r}_{1}^{2} + {r}_{2}^{2}}{2} \qquad ( 9 )$$

The laser controller 13 calculates the center wavelength λ₀ by converting the radius rₘ calculated based on the above expression (9) into the wavelength λ by the above expression (8). Further, the laser controller 13 converts the interference fringes into the spectral waveform using the above expression (8), and calculates the spectral line width E95 based on the above expression (3).

### 3.4 Operation

Next, operation of the laser device 2 according to the first embodiment will be described. Similarly to the comparative example, the laser controller 13 turns on the switch 22a in synchronization with the light emission trigger Tr, so that the pulse laser light PL is output from the oscillation device 10, and the pulse width W is extended by the OPS 11. The pulse laser light PL output from the OPS 11 enters the monitor module 12. In the monitor module 12, the pulse energy and the spectrum are measured. The laser controller 13 calculates the spectral line width E95 and the center wavelength λ₀ based on the measurement data of the spectrum.

The pulse laser light PL having passed through the monitor module 12 enters the beam measurement device 14. In the beam measurement device 14, the beam intensity distribution, the beam angle distribution, and the pulse waveform are measured. The laser controller 13 calculates the etendue ET and the pulse width TIS based on the measurement data of the beam intensity distribution, the beam angle distribution, and the pulse waveform. Then, the laser controller 13 calculates the SC using the calculated etendue ET, spectral line width E95, and pulse width TIS.

The laser controller 13 causes the display device 15 to display the calculated SC and transmits the calculated SC to the exposure apparatus 3. The pulse laser light PL having passed through the beam measurement device 14 enters the exposure apparatus 3. Other operation of the laser device 2 according to the present embodiment is similar to that of the comparative example.

### 3.5 Effect

Since the laser device 2 according to the present embodiment calculates the SC based on the measurement data of the spectrum, the beam intensity distribution, the beam angle distribution, and the pulse waveform, it is possible to detect deterioration of the SC in a state in which the exposure apparatus 3 is connected to the laser device 2 without using the SC measurement device 4. As a result, necessary maintenance can be performed as appropriate, and thus the quality of exposure by the exposure apparatus 3 can be maintained at a high quality.

### 4. Second Embodiment

Next, the laser device 2 according to a second embodiment of the present disclosure will be described. Hereinafter, the same component as that in the first embodiment is denoted by the same reference numeral, and description thereof will be omitted as appropriate.

### 4.1 Overall Configuration

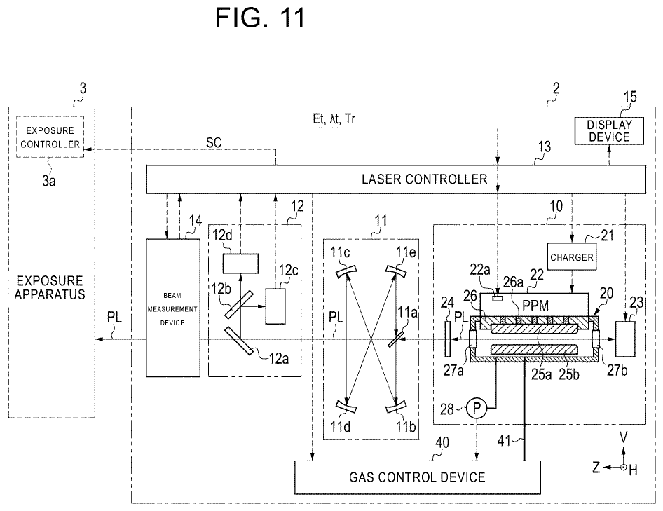

FIG. 11 schematically shows the configuration of the laser device 2 according to the second embodiment. In addition to the oscillation device 10, the OPS 11, the monitor module 12, the laser controller 13, the beam measurement device 14, and the display device 15, the laser device 2 according to the present embodiment includes a gas control device 40 and a pressure sensor 28 for detecting the gas pressure of the laser gas enclosed in the chamber 20.

The gas control device 40 is connected to the chamber 20 via a gas pipe, and adjusts the pulse width TIS by controlling the concentration of the halogen gas in the chamber 20. The gas control device 40 is an example of the “pulse width changing device” according to the technology of the present disclosure.

In the present embodiment, the laser controller 13 controls the gas pressure via the gas control device 40 to adjust the pulse width TIS so that the calculated SC is equal to or less than a target value SCt.

### 4.2 Gas Control Device

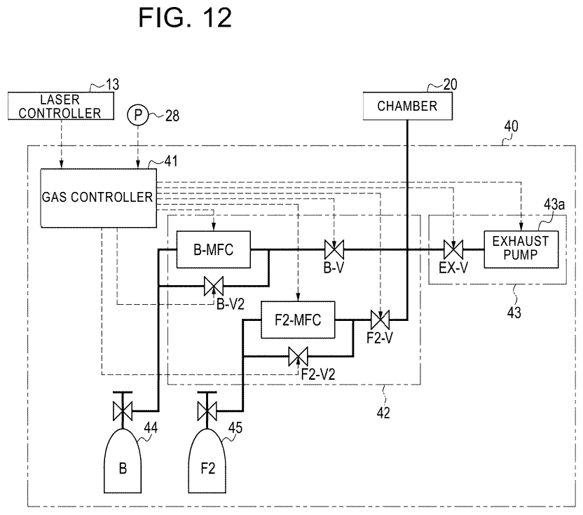

FIG. 12 schematically shows the configuration of the gas control device 40. The gas control device 40 includes a gas controller 41, a laser gas supply device 42, and an exhaust device 43. The laser gas supply device 42 is connected to a first gas supply source 44, a second gas supply source 45, the chamber 20, and the exhaust device 43 via a gas pipe.

The first gas supply source 44 is a container containing, for example, a first gas obtained by mixing an argon (Ar) gas and a neon (Ne) gas, which are inert gases. The first gas is a buffer gas. The second gas supply source 45 is a container containing, for example, a second gas obtained by mixing a fluorine (F₂) gas, which is a halogen gas, with an argon (Ar) gas and a neon (Ne) gas, which are inert gases.

The laser gas supply device 42 includes a first gas injection valve B-V, a mass flow controller B-MFC, a bypass valve B-V2, a second gas injection valve F2-V, a mass flow controller F2-MFC, and a bypass valve F2-V2. The mass flow controller B-MFC controls the flow rate of the first gas. The mass flow controller F2-MFC controls the flow rate of the second gas. The exhaust device 43 includes an exhaust valve EX-V and an exhaust pump 43a.

The gas controller 41 transmits and receives signals to and from the laser controller 13, and further receives data of the gas pressure from the pressure sensor 28. The gas controller 41 controls each of the laser gas supply device 42 and the exhaust device 43.

When the laser gas in the chamber 20 is to be replaced, the gas controller 41 drives the exhaust pump 43a and then opens the exhaust valve EX-V to set the gas pressure detected by the pressure sensor 28 to a predetermined pressure equal to or lower than the atmospheric pressure. Then, the gas controller 41 closes the exhaust valve EX-V and opens the second gas injection valve F2-V to inject a predetermined amount of the second gas into the chamber 20. Then, the gas controller 41 closes the second gas injection valve F2-V and opens the first gas injection valve B-V to inject the first gas into the chamber 20, thereby setting the gas pressure in the chamber 20 to the predetermined pressure. As a result, the oscillation device 10 is in a state in which laser oscillation is possible to be performed.

When the oscillation device 10 is performing laser oscillation, the gas controller 41 controls the first gas injection valve B-V and the exhaust valve EX-V so that the charge voltage of the charger 21 falls within a predetermined range.

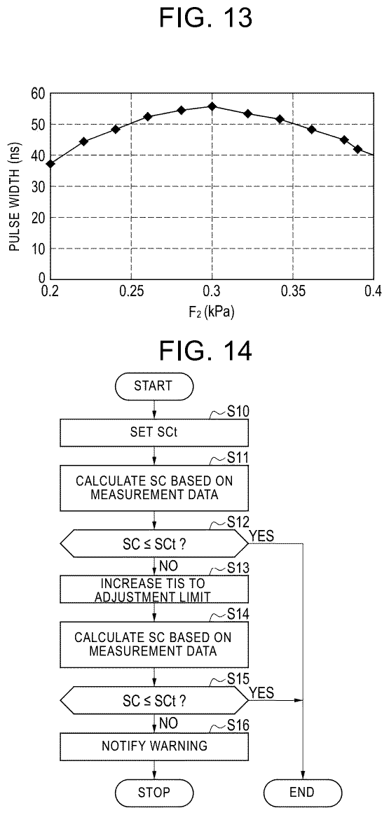

In Japanese Patent Application Publication No. 2001-267662, it is disclosed that the pulse width of the laser light changes in accordance with the pressure of the F2 gas in the chamber, as shown in FIG. 13. This means that the pulse width TIS changes depending on the concentration of the halogen gas in the chamber 20. Therefore, the pulse width TIS can be adjusted by controlling the concentration of the halogen gas by the gas controller 41.

When adjusting the pulse width TIS, in a case of relatively decreasing the concentration of the halogen gas, the gas controller 41 opens the first gas injection valve B-V and injects the first gas into the chamber 20. Alternatively, when adjusting the pulse width TIS, in a case of relatively increasing the concentration of the halogen gas, the gas controller 41 opens the second gas injection valve F2-V and injects the second gas into the chamber 20. The injection amounts of the first gas and the second gas are preferably determined by acquiring characteristics as shown in FIG. 13 within a range in which the laser performance can be maintained.

### 4.3 Operation

Next, operation of the laser device 2 according to the second embodiment will be described. Since operation related to the calculation of the SC is similar to that of the first embodiment, operation related to control of the SC will be described.

FIG. 14 schematically shows a flow of control of the SC. First, the laser controller 13 sets the target value SCt (step S10). The laser controller 13 may acquire the target value SCt from the exposure apparatus 3 or may store it in advance.

Next, the laser controller 13 calculates the SC based on the measurement data of the spectrum, the beam intensity distribution, the beam angle distribution, and the pulse waveform described above (step S11). The laser controller 13 determines whether or not the calculated SC is equal to or less than the target value SCt (step S12). When the SC is equal to or less than the target value SCt (step S12:YES), the laser controller 13 ends the control of the SC.

When the SC is greater than the target value SCt (step S12:NO), the laser controller 13 increases the pulse width TIS to an adjustment limit by controlling the gas control device 40 (step S13). The adjustment limit is determined by the performance of the laser device 2.

After increasing the pulse width TIS, the laser controller 13 calculates the SC again based on the measurement data (step S14). The laser controller 13 determines whether or not the calculated SC is equal to or less than the target value SCt (step S15). When the SC is equal to or less than the target value SCt (step S15:YES), the laser controller 13 ends the control of the SC.

When the SC is greater than the target value SCt (step S15:NO), the laser controller 13 stops the control of the SC by notifying a warning (step S16). For example, the laser controller 13 notifies a warning by displaying a message on the display device 15.

### 4.4 Effect

Since the laser device 2 according to the present embodiment includes the gas control device 40, it is possible to control the SC so as to be maintained equal to or less than the target value SCt. As a result, the quality of exposure by the exposure apparatus 3 can be maintained at a high quality.

### 4.5 Modification

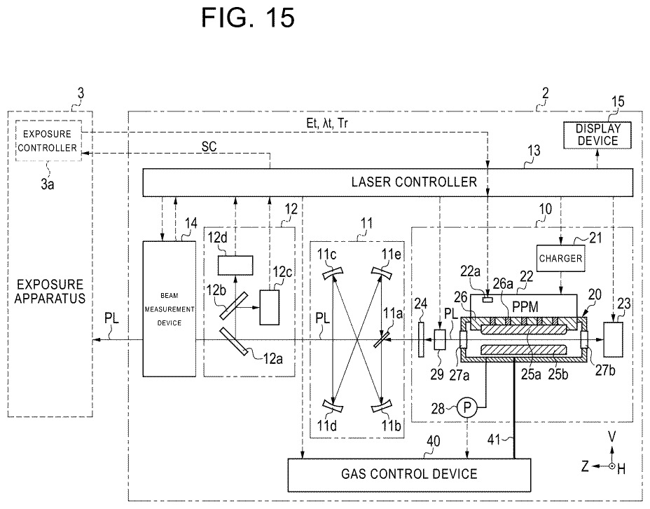

Next, a modification of the second embodiment will be described. FIG. 15 schematically shows the configuration of the laser device 2 according to a modification of the second embodiment. The laser device 2 according to the present modification differs from the configuration of the second embodiment only in that a wavefront changing device 29 that allows the spectral line width E95 to be adjusted is further included.

The wavefront changing device 29 is arranged on the optical axis of the optical resonator in the oscillation device 10. For example, the wavefront changing device 29 is arranged on the optical path of the pulse laser light PL between the front-side window 27a and the output coupling mirror 24. The wavefront changing device 29 adjusts the spectral line width E95 by changing the wavefront of the pulse laser light PL based on control of the laser controller 13. The wavefront changing device 29 is an example of the “spectral line width changing device” according to the technology of the present disclosure.

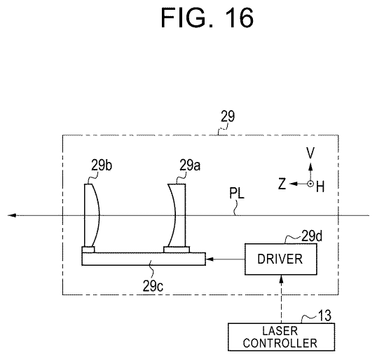

FIG. 16 schematically shows the configuration of the wavefront changing device 29. The wavefront changing device 29 includes a cylindrical plano-concave lens 29a, a cylindrical plano-convex lens 29b, a linear stage 29c, and a driver 29d. Both surfaces of the cylindrical plano-concave lens 29a are each formed with a reflection-reducing film. A convex surface of the cylindrical plano-convex lens 29b is formed with a reflection-reducing film. The cylindrical plano-convex lens 29b may be formed with a partial reflection film on a flat surface thereof so as to function as an output coupling mirror. In this case, the output coupling mirror 24 may be omitted.

The linear stage 29c allows the cylindrical plano-concave lens 29a to move in the Z direction. The driver 29d drives the linear stage 29c based on control of the laser controller 13.

When the laser controller 13 transmits a control signal to the wavefront changing device 29, the distance between the cylindrical plano-concave lens 29a and the cylindrical plano-convex lens 29b is changed by the driver 29d. As a result, the wavefront of the pulse laser light PL that reciprocates in the optical resonator is changed, and the spectral line width E95 selected by the grating in the line narrowing device 23 is changed. Thus, the spectral line width E95 can be adjusted.

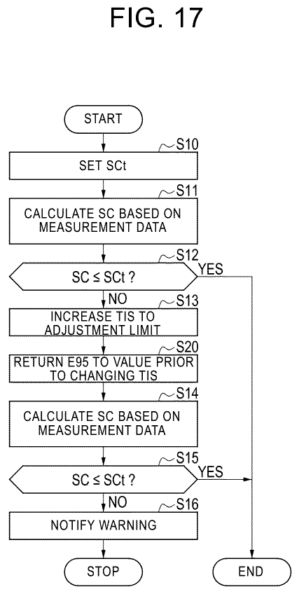

FIG. 17 schematically shows a flow of control of the SC according to the modification of the second embodiment. The flowchart shown in FIG. 17 differs from the flowchart shown in FIG. 14 only in that step S20 is added after step S13. In the present modification, the laser controller 13 controls the gas control device 40 to increase the pulse width TIS to the adjustment limit, and then controls the wavefront changing device 29 to return the spectral line width E95 to a value prior to changing the pulse width TIS (step S20). The value prior to changing the pulse width TIS is the value of the pulse width TIS calculated in step S11.

It is preferable that the spectral line width E95 does not fluctuate because it has a large effect on the exposure performance, but the spectral line width E95 may fluctuate by changing the pulse width TIS. Accordingly, in the present modification, when the pulse width TIS is increased, the spectral line width E95 is returned to a value prior to changing the pulse width TIS. Therefore, in the present modification, even when the SC is set to be equal to or less than the target value SCt by the gas control device 40, it is possible to suppress fluctuation in the spectral line width E95, and the quality of exposure by the exposure apparatus 3 can be maintained at a high quality.

### 5. Third Embodiment

The laser device 2 according to a third embodiment of the present disclosure will be described. Hereinafter, the same component as that in the modification of the second embodiment is denoted by the same reference numeral, and description thereof will be omitted as appropriate.

### 5.1 Overall Configuration

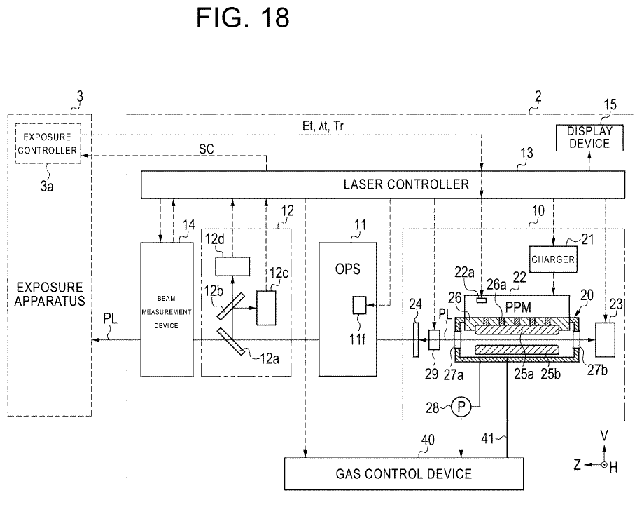

FIG. 18 schematically shows the configuration of the laser device 2 according to the third embodiment. The laser device 2 according to the present embodiment differs from the configuration of the laser device 2 according to the modification of the second embodiment only in that an actuator 11f for changing the etendue ET is provided in the OPS 11. The OPS 11 provided with the actuator 11f is an example of the “etendue changing device” according to the technology of the present disclosure.

### 5.2 OPS

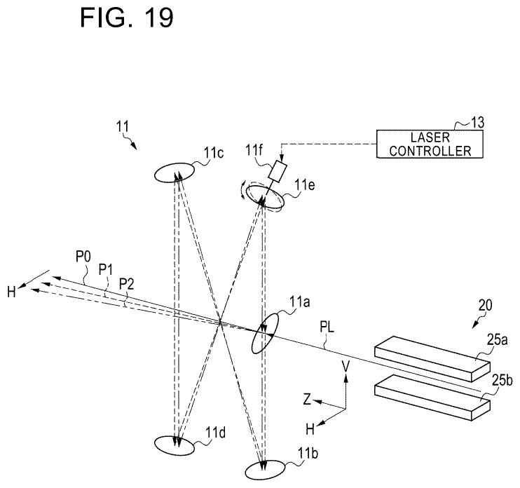

FIG. 19 schematically shows the configuration of the OPS 11 according to the third embodiment. In the present embodiment, the actuator 11f is connected to the concave mirror 11e among the concave mirrors 11b to 11e. The actuator 11f is configured to be capable of changing the posture of the concave mirror 11e, and operation thereof is controlled by the laser controller 13. Here, not limited to the concave mirror 11e, the actuator 11f may be connected to another concave mirror.

In the present embodiment, the actuator 11f changes the posture of the concave mirror 11e so that the optical path of the pulse laser light PL output from the OPS 11 is shifted in the H direction each time the pulse laser light PL circulates through the delay optical path. In FIG. 19, P0 indicates the optical path of the pulse laser light PL output from the OPS 11 without circulating through the delay optical path. P1 represents the optical path of the pulse laser light PL output from the OPS 11 after circulating through the delay optical path once. P2 represents the optical path of the pulse laser light PL output from the OPS 11 after circulating through the delay optical path twice.

The laser controller 13 controls the beam divergence angle 22 by controlling the shift amount of the optical path of the pulse laser light PL output from the OPS 11 in the H direction by the actuator 11f. The larger the shift amount in the H direction is, the larger the beam divergence angle 22 in the H direction is. By thus changing the beam divergence angle 22, the etendue ET is changed.

Here, since the delay optical path length L of the OPS 11 is set longer than the temporal coherence length CL of the pulse laser light PL, interference of the pulse laser light PL of the optical paths P0 to P2 does not occur.

### 5.3 Operation

Next, operation of the laser device 2 according to the third embodiment will be described. Since operation related to the calculation of the SC is similar to that of the first embodiment, operation related to control of SC will be described.

### 5.3.1 Adjustment Example of Control Parameter of SC

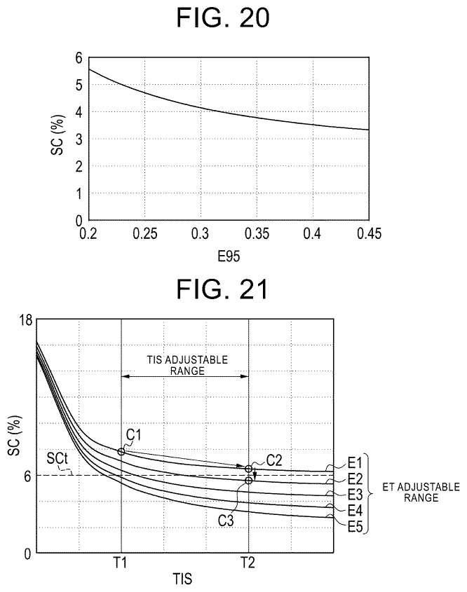

In the present embodiment, the SC can be controlled by adjusting three control parameters being the pulse width TIS, the spectral line width E95, and the etendue ET. As shown in FIG. 20, the SC can be decreased by increasing the spectral line width E95. However, generally, when the spectral line width E95 is changed, imaging performance of the exposure apparatus 3 is changed. Therefore, it is preferable to reduce the adjustment amount of the spectral line width E95. When the etendue ET is changed, the amount of light entering the entrance aperture of the exposure apparatus 3 is changed. Therefore, it is preferable to reduce the adjustment amount of the etendue ET. Accordingly, when the SC is controlled, it is preferable to adjust the control parameters in the order of the pulse width TIS, the etendue ET, and the spectral line width E95.

FIG. 21 shows an adjustment example of the control parameters of the SC. FIG. 21 shows the relationship among the pulse width TIS, the etendue ET, and the SC. E1 to E5 indicate different etendues ET. The adjustable range of the pulse width TIS is the range of T1 to T2. The adjustable range of the etendue ET is the range of E1 to E5. The TIS adjustable range and the ET adjustable range are determined by the performance of the laser device 2. In the present adjustment example, the target value SCt of the SC is set to 6%.

For example, it is assumed that the control parameters correspond to a condition C1 and the value of SC is about 8% in a case in which the SC is calculated based on the measurement data described above. In the condition C1, the pulse width TIS is T1, and the etendue ET is E1. In this case, the control parameters are set to a condition C2 by increasing the pulse width TIS from T1 to T2 while maintaining the etendue ET at E1. In the condition C2, since the SC exceeds the target value SCt, the control parameters are set to a condition C3 by increasing the etendue ET from E1 to E2 while maintaining the pulse width TIS at T2. In the condition C3, since the SC is equal to or less than the target value SCt, the control is ended without adjusting the spectral line width E95.

In the adjustment example described above, the pulse width TIS is increased from T1 to T2, which is the adjustment limit, at once, but the SC may be calculated while increasing the pulse width TIS by a constant amount up to the adjustment limit.

### 5.3.2 Control Flow of SC

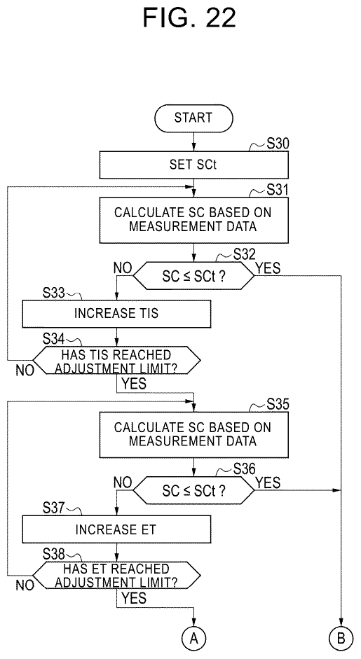

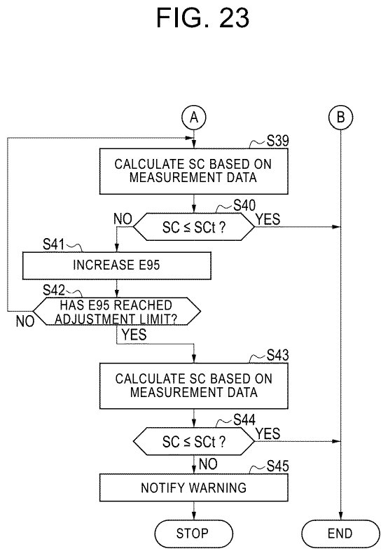

FIGS. 22 and 23 schematically show a flow of control of the SC according to the third embodiment. First, the laser controller 13 sets the target value SCt (step S30). The laser controller 13 may acquire the target value SCt from the exposure apparatus 3 or may store it in advance.

Next, the laser controller 13 calculates the SC based on the measurement data of the spectrum, the beam intensity distribution, the beam angle distribution, and the pulse waveform described above (step S31). The laser controller 13 determines whether or not the calculated SC is equal to or less than the target value SCt (step S32). When the SC is equal to or less than the target value SCt (step S32:YES), the laser controller 13 ends the control of SC.

When the SC is greater than the target value SCt (step S32:NO), the laser controller 13 increases the pulse width TIS by a constant amount by controlling the gas control device 40 (step S33). The laser controller 13 determines whether or not the pulse width TIS after being increased by a constant amount has reached the adjustment limit (step S34). When the pulse width TIS has not reached the adjustment limit (step S34:NO), the laser controller 13 returns processing to step S31.

When the pulse width TIS has reached the adjustment limit (step S34:YES), the laser controller 13 calculates the SC based on the measurement data (step S35). The laser controller 13 determines whether or not the calculated SC is equal to or less than the target value SCt (step S36). When the SC is equal to or less than the target value SCt (step S36:YES), the laser controller 13 ends the control of SC.

When the SC is greater than the target value SCt (step S36:NO), the laser controller 13 increases the etendue ET by a constant amount by controlling the actuator 11f of the OPS 11 (step S37). The laser controller 13 determines whether or not the etendue ET after being increased by a constant amount has reached the adjustment limit (step S38). When the etendue ET has not reached the adjustment limit (step S38:NO), the laser controller 13 returns processing to step S35.

When the etendue ET has reached the adjustment limit (step S38:YES), the laser controller 13 calculates the SC based on the measurement data (step S39). The laser controller 13 determines whether or not the calculated SC is equal to or less than the target value SCt (step S40). When the SC is equal to or less than the target value SCt (step S40:YES), the laser controller 13 ends the control of SC.

When the SC is greater than the target value SCt (step S40:NO), the laser controller 13 increases the spectral line width E95 by a constant amount by controlling the wavefront changing device 29 (step S41). The laser controller 13 determines whether or not the spectral line width E95 after being increased by a constant amount has reached the adjustment limit (step S42). When the spectral line width E95 has not reached the adjustment limit (step S42:NO), the laser controller 13 returns processing to step S39.

When the spectral line width E95 has reached the adjustment limit (step S42:YES), the laser controller 13 calculates the SC based on the measurement data (step S43). The laser controller 13 determines whether or not the calculated SC is equal to or less than the target value SCt (step S44). When the SC is equal to or less than the target value SCt (step S44:YES), the laser controller 13 ends the control of the SC.

When the SC is greater than the target value SCt (step S44:NO), the laser controller 13 stops the control of the SC by notifying a warning (step S45).

### 5.4 Effect

In the present embodiment, when controlling the SC, since the control parameters are adjusted in order from those having less effect on the exposure performance, it is possible to suppress a decrease in the exposure performance due to the control of the SC.

### 6. Modification of Pulse Width Changing Device

Next, various modifications of the pulse width changing device will be described. Although the gas control device 40 is used as the pulse width changing device in the second embodiment and the third embodiment, the pulse width changing device described below can be used instead of the gas control device 40 or in addition to the gas control device 40.

### 6.1 First Modification

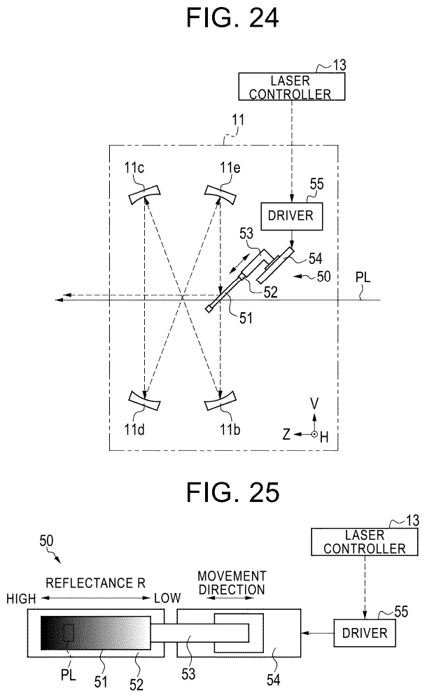

FIG. 24 schematically shows the configuration of the pulse width changing device according to a first modification. The pulse width changing device according to the present modification is configured by the OPS 11 provided with a reflectance-variable beam splitter device 50 instead of the beam splitter 11a. The configuration of the concave mirrors 11b to 11e is similar to that of the comparative example.

FIG. 25 schematically shows the configuration of the reflectance-variable beam splitter device 50. The reflectance-variable beam splitter device 50 includes a beam splitter 51 having a reflectance distribution, a holder 52, a fixed angle 53, a linear stage 54, and a driver 55. The beam splitter 51 has a rectangular shape, and a reflectance R thereof changes in the longitudinal direction. The holder 52 holds the beam splitter 51 and is connected to the linear stage 54 via the fixed angle 53.

The beam splitter 51 is arranged on the optical path of the pulse laser light PL output from the oscillation device 10. The linear stage 54 moves the beam splitter 51 in a direction in which the reflectance R changes with the incident angle of the pulse laser light PL on the beam splitter 51 being constant. The driver 55 drives the linear stage 54 based on a control signal transmitted from the laser controller 13.

Basically, as the reflectance R at the position of the beam splitter 51 where the pulse laser light PL is incident becomes higher, components of the pulse laser light PL that circulate through the delay optical path of the OPS 11 increases, so that the pulse width TIS of the pulse laser light PL output from the OPS 11 becomes longer.

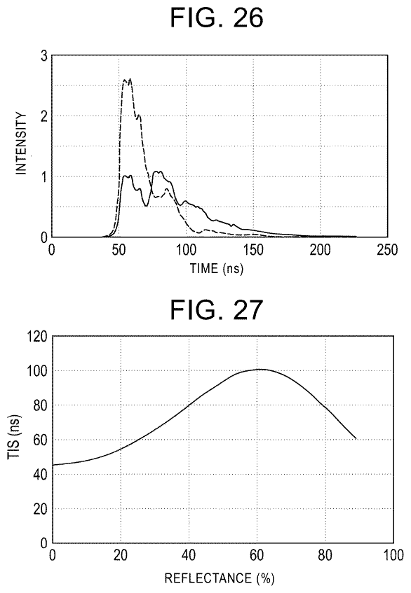

FIG. 26 shows an example of the pulse waveforms before and after extension by the OPS 11. In FIG. 26, a broken line represents the pulse waveform of the pulse laser light PL output from the oscillation device 10. A solid line represents the pulse waveform of the pulse laser light PL extended by the OPS 11. This is an experimental result in which the delay optical path length L is set to 11.5 meters and the reflectance R at the position where the pulse laser light PL is incident is set to 60%. The pulse width TIS of the pulse laser light PL output from the oscillation device 10 was about 44 ns, and the pulse width TIS of the pulse laser light PL extended by the OPS 11 was about 100 ns.

FIG. 27 shows an example of the relationship between the reflectance R and the pulse width TIS. According to FIG. 27, it can be seen that the pulse width TIS changes from about 44 ns to about 100 ns by changing the reflectance R from 0% to 60%.

In the present modification, the laser controller 13 stores data representing the relationship between the reflectance R and the pulse width TIS in advance. When adjusting the pulse width TIS, the laser controller 13 obtains the value of the reflectance R corresponding to a target pulse width TIS, and moves the beam splitter 51 as transmitting a control signal to the driver 55 so that the reflectance R at the position where the pulse laser light PL is incident becomes the obtained value.

### 6.2 Second Modification

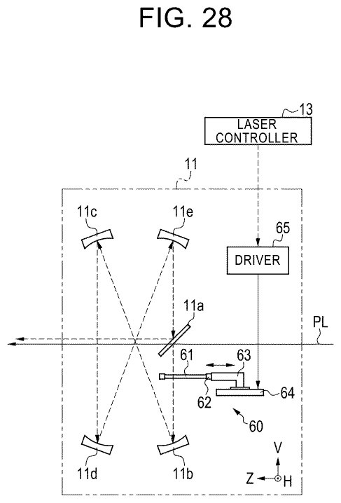

FIG. 28 schematically shows the configuration of the pulse width changing device according to a second modification. The pulse width changing device according to the present modification is configured by adding a variable-transmittance ND filter device 60 to the OPS 11 according to the comparative example. The configurations of the beam splitter 11a and the concave mirrors 11b to 11e are similar to those of the comparative example.

The variable-transmittance ND filter device 60 includes a neutral density (ND) filter 61 having a transmittance, a holder 62, a fixed angle 63, a linear stage 64, and a driver 65. The ND filter 61 has a rectangular shape, and the transmittance thereof changes in the longitudinal direction. The holder 62 holds the ND filter 61, and is connected to the linear stage 64 via the fixed angle 63.

The ND filter 61 is arranged on the delay optical path of the OPS 11. In the present modification, the ND filter 61 is arranged on the delay optical path between the beam splitter 11a and the concave mirror 11b such that the pulse laser light PL is incident thereon perpendicularly. The linear stage 64 moves the ND filter 61 in a direction in which the transmittance changes with the incident angle of the pulse laser light PL on the ND filter 61 being constant. The driver 65 drives the linear stage 64 based on a control signal transmitted from the laser controller 13.

Basically, as the transmittance at the position of the ND filter 61 where the pulse laser light PL is incident becomes higher, components of the pulse laser light PL that circulate through the delay optical path of the OPS 11 increases, so that the pulse width TIS of the pulse laser light PL output from the OPS 11 becomes longer.

In the present modification, the laser controller 13 stores data representing the relationship between the transmittance and the pulse width TIS in advance. When adjusting the pulse width TIS, the laser controller 13 obtains the value of the transmittance corresponding to the target pulse width TIS, and moves the ND filter 61 as transmitting a control signal to the driver 55 so that the transmittance at the position where the pulse laser light PL is incident becomes the obtained value.

### 6.3 Third Modification

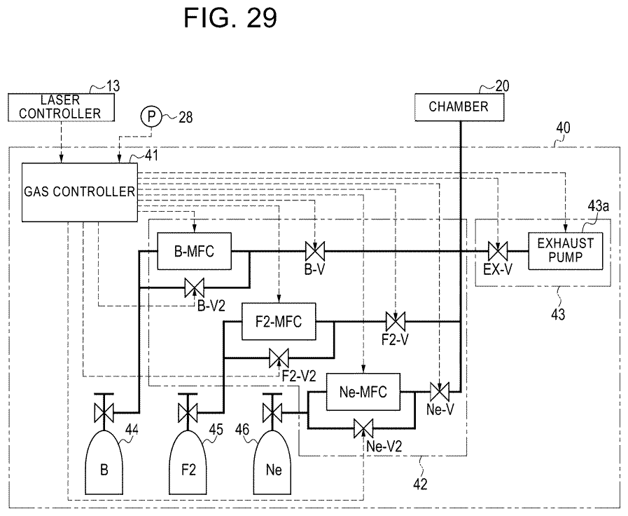

FIG. 29 schematically shows the configuration of the pulse width changing device according to a third modification. The pulse width changing device according to the present modification is configured by adding a third gas supply source 46, a third gas injection valve Ne-V, a mass flow controller Ne-MFC, and a bypass valve Ne-V2 to the gas control device 40 according to the second embodiment. The third gas injection valve Ne-V, the mass flow controller Ne-MFC, and the bypass valve Ne-V2 are included in the laser gas supply device 42. The third gas supply source 46 is a container containing a neon (Ne) gas as a third gas.

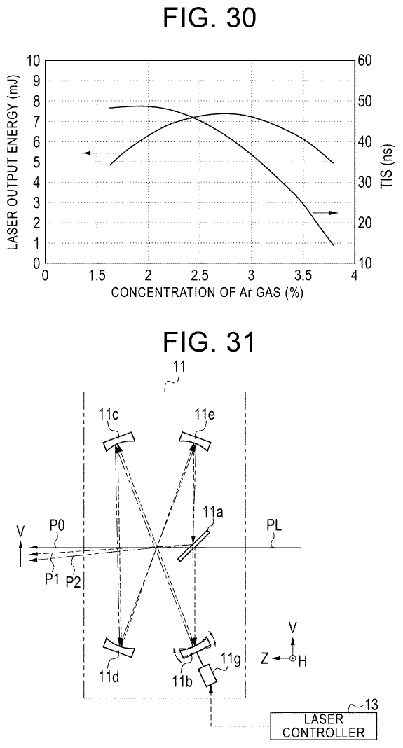

In U.S. Pat. No. 6,584,131, it is disclosed that the pulse width TIS of the laser light changes in accordance with the concentration of the Ar gas in the chamber, as shown in FIG. 30. Therefore, the pulse width TIS can be adjusted by controlling the concentration of the Ar gas by the gas controller 41. In the present modification, the gas controller 41 adjusts the pulse width TIS by injecting the third gas into the chamber 20 to control the concentration of the Ar gas.

The injection amount of the third gas is preferably determined as acquiring characteristics as shown in FIG. 30 within a range in which the laser performance can be maintained. It is preferable that the gas controller 41 controls the concentration of the Ar gas by determining the injection amount of the third gas using characteristics of a region in which the pulse width TIS increases as the concentration of the Ar gas decreases.

The control of the SC according to the present modification is similar to the control described in the second embodiment except that the third gas is injected into the chamber 20 to control the concentration of the Ar gas when adjusting the pulse width TIS. The pulse width TIS may be adjusted through combination of two or more pulse width changing devices of the plurality of pulse width changing devices described in the second embodiment and the first to third modifications.

### 7. Modification of Etendue Changing Device

Next, various modifications of the etendue changing device will be described. Instead of the etendue changing device according to the third embodiment or in addition to the etendue changing device according to the third embodiment, the etendue changing device described below can be used.

### 7.1 First Modification

FIG. 31 schematically shows the configuration of the etendue changing device according to a first modification. The etendue changing device according to the present modification is configured by connecting an actuator 11g to the concave mirror 11b of the concave mirrors 11b to 11e included in the OPS 11. The actuator 11g is configured to be capable of changing the posture of the concave mirror 11b, and operation thereof is controlled by the laser controller 13. Here, not limited to the concave mirror 11b, the actuator 11g may be connected to another concave mirror.

In the present modification, the actuator 11g changes the posture of the concave mirror 11b so that the optical path of the pulse laser light PL output from the OPS 11 is shifted in the V direction each time the pulse laser light PL circulates through the delay optical path.

In the present modification, the laser controller 13 controls the beam divergence angle Ω by controlling the shift amount of the optical path of the pulse laser light PL output from the OPS 11 in the V direction by the actuator 11g. The larger the shift amount in the V direction is, the larger the beam divergence angle Ω in the V direction is. By thus changing the beam divergence angle Ω, the etendue ET is changed.

Here, the actuator 11g may be provided in the OPS 11 according to the third embodiment. That is, the shift amounts of the optical path of the pulse laser light PL output from the OPS 11 in the H direction and in the V direction may be controlled by the actuator 11f and the actuator 11g, respectively. As a result, the beam divergence angle 22 can be increased in the H direction and the V direction.

Alternatively, the shift amounts of the optical path of the pulse laser light PL in the H direction and in the V direction may be controlled by arranging the OPS 11 according to the third embodiment and the OPS 11 according to the present modification in series on the optical path of the pulse laser light PL.

### 7.2 Second Modification

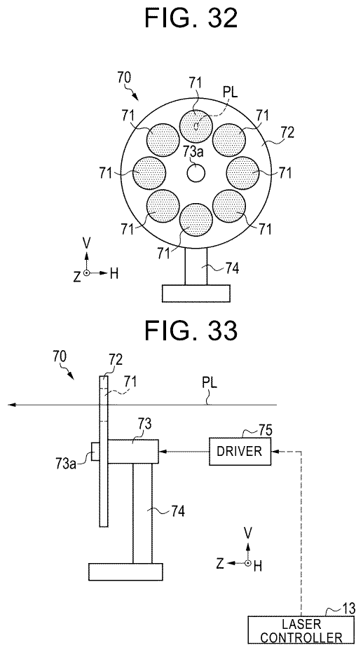

FIGS. 32 and 33 schematically show the configuration of the etendue changing device according to a second modification. The etendue changing device according to the present modification is configured by a rotation optical device 70 that allows a plurality of optical elements 71 having different optical characteristics to be selectively arranged on the optical path of the pulse laser light PL. The rotation optical device 70 includes the plurality of optical elements 71, a rotation holder 72, a servo motor 73, a fixed angle 74, and a driver 75.

The rotation holder 72 has a disk shape, and holds the plurality of optical elements 71. The plurality of optical elements 71 are arranged on a circle concentric to the center of the rotation holder 72. The center of the rotation holder 72 is connected to a rotation shaft 73a of the servo motor 73. The servo motor 73 rotates the rotation holder 72. The fixed angle 74 holds the servo motor 73. The driver 75 drives the linear stage 54 based on a control signal transmitted from the laser controller 13.

The plurality of optical elements 71 are to be sequentially arranged on the optical path of the pulse laser light PL output from the oscillation device 10 as the rotation holder 72 rotates. The rotation optical device 70 is arranged between the oscillation device 10 and the OPS 11, for example.

Each of the optical elements 71 is an optical element that allows the beam angle distribution or the beam intensity distribution of the pulse laser light PL to be changed. For example, the plurality of optical elements 71 have different characteristics of changing the beam angle distribution or the beam intensity distribution.

Each of the optical elements 71 is a diffusion plate, a diffractive optical element (DOE), a computer-generated hologram (CGH), a kinoform, or the like, and can output the pulse laser light PL incident thereon with the etendue ET increased. With the optical elements 71, it is possible to increase the beam angle distribution or the beam intensity distribution in only one of the V direction and the H direction.

In the present modification, when controlling the SC, the laser controller 13 rotates the rotation holder 72 to select the optical element 71 to be arranged on the optical path of the pulse laser light PL, thereby adjusting the etendue ET.

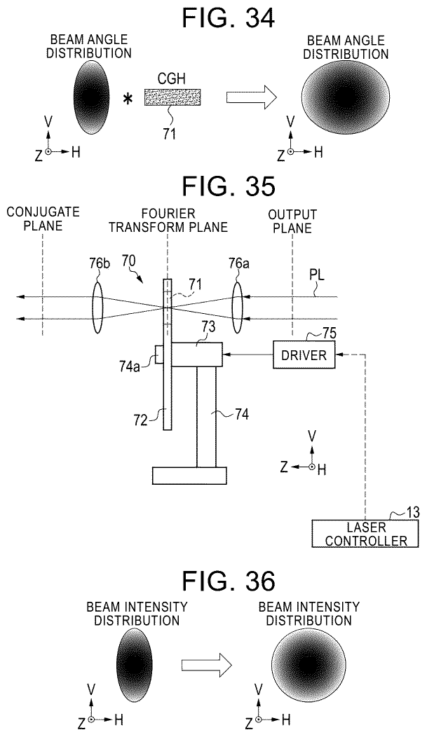

For example, the etendue ET can be increased by arranging the diffusion plate as the optical element 71 on the optical path of the pulse laser light PL to increase the beam divergence angle Ω. Further, by providing the optical element 71 with an effect of increasing the beam angle distribution in only one of the V direction and the H direction, it is possible to increase the beam divergence angle Ω in only one of the V direction and the H direction. For example, as shown in FIG. 34, by using a CGH having an effect of increasing the beam angle distribution in only the H direction as the optical element 71, it is possible to increase the beam divergence angle Ω in only the H direction.

In a case of adjusting the beam intensity distribution, the optical element 71 may be arranged on a Fourier transform plane with respect to an output surface of the oscillation device 10. In this case, as shown in FIG. 35, on the optical path of the pulse laser light PL output from the oscillation device 10, an incident optical system 76a is arranged on an incident side of the optical element 71, and an exit optical system 76b is arranged on an output side. The incident optical system 76a and the exit optical system 76b are arranged to have a common focal plane and the optical elements 71 of the second rotation optical device 70b are positioned on the focal plane. Thus, the incident optical system 76a performs Fourier transform on an image of the pulse laser light PL to the position of the optical element 71. That is, in the example shown in FIG. 35, the optical element 71 is arranged on the Fourier transform plane.

The beam intensity distribution is changed by the convolution of the beam intensity distribution on the output surface and the optical characteristics of the optical element 71. That is, it is possible to adjust the beam intensity distribution on a conjugate plane conjugate to the output plane by the optical characteristics of the optical element 71. As shown in FIG. 36, for example, by using a DOE as the optical element 71, it is possible to expand the beam intensity distribution on the output surface in the H direction.

Here, a prism, a zoom lens, and the like can be used as the optical element 71 to change the beam angle distribution or the beam intensity distribution.

### 7.3 Third Modification

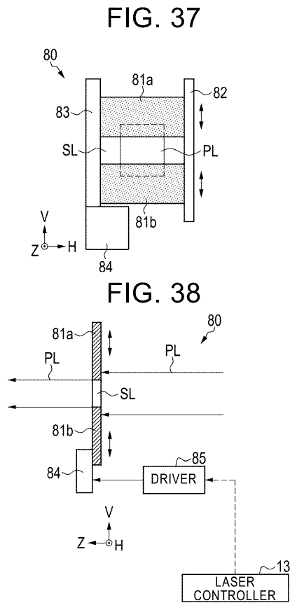

FIGS. 37 and 38 schematically show the configuration of the etendue changing device according to a third modification. The etendue changing device according to the present modification is configured by a variable slit device 80 that allows a slit width to be changed in one direction. The variable slit device 80 includes a pair of plates 81a, 81b, a guide 82, a power transmission mechanism 83, an actuator 84, and a driver 85.

The pair of plates 81a, 81b are held by the guide 82 so as to be movable in the V direction. The power transmission mechanism 83 is connected to the actuator 84 and changes the distance between the pair of plates 81a, 81b by the actuator 84. An opening between the pair of plates 81a, 81b serve as a slit SL through which the pulse laser light PL output from the oscillation device 10 passes.

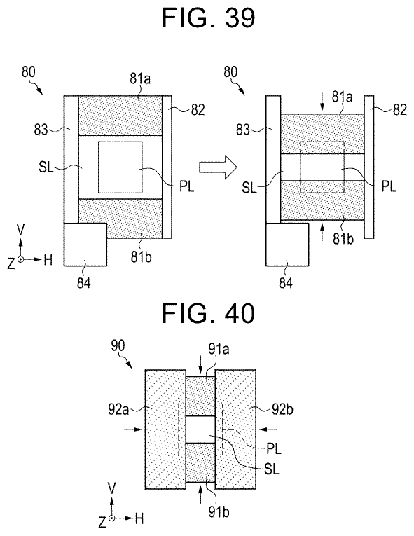

In the present modification, when controlling the SC, the laser controller 13 drives the actuator 84 to adjust the width of the slit SL, thereby adjusting the etendue ET. As shown in FIG. 39, when the width of the slit SL is narrowed from a state in which the width of the slit SL is wide, the beam intensity distribution or the beam angle distribution is suppressed in the V direction, and thus the etendue ET is reduced.

### 7.4 Fourth Modification

FIG. 40 schematically shows the configuration of the etendue changing device according to a fourth modification. The etendue changing device according to the present modification is configured by a variable slit device 90 that allows the slit width to be changed in two directions. The variable slit device 90 includes a pair of plates 91a, 91b and a pair of plates 92a, 92b. The variable slit device 90 includes guides, a power transmission mechanism, an actuator, and a driver similar to those of the third modification.

The pair of plates 91a, 91b are held by the guide so as to be movable in the V direction. The pair of plates 92a, 92b are held by the guide so as to be movable in the H direction. An opening between the pair of plates 91a, 91b and between the pair of plates 92a, 92b serve as the slit SL through which the pulse laser light PL output from the oscillation device 10 passes.

In the present modification, when controlling the SC, the laser controller 13 drives the actuator to adjust the widths of the slit SL in the V direction and in the H direction, thereby adjusting the etendue ET.

In the present modification, since the width of the slit SL can be freely adjusted in the V direction and in the H direction, the beam divergence angle 22 can also be measured using the variable slit device 90.

### 7.5 Fifth Modification

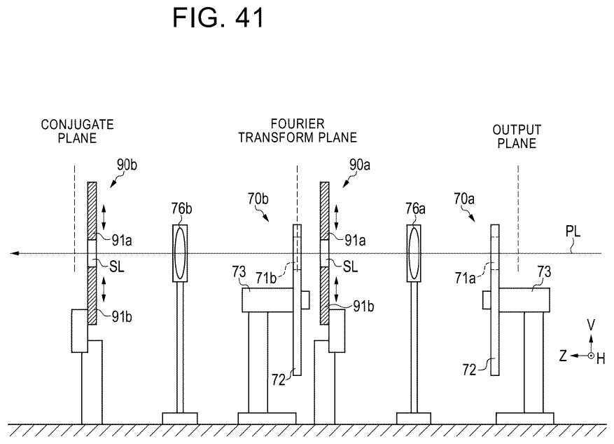

FIG. 41 schematically shows the configuration of the etendue changing device according to a fifth modification. The etendue changing device according to the present modification is configured by combining a plurality of etendue changing devices.

The etendue changing device according to the present modification includes a first rotation optical device 70a, the incident optical system 76a, a first variable slit device 90a, a second rotation optical device 70b, the exit optical system 76b, and a second variable slit device 90b. The first rotation optical device 70a, the incident optical system 76a, the first variable slit device 90a, the second rotation optical device 70b, the exit optical system 76b, and the second variable slit device 90b are arranged in this order on the optical path of the pulse laser light PL output from the oscillation device 10.

The first rotation optical device 70a and the second rotation optical device 70b have similar configurations to the rotation optical device 70 according to the second modification. The first variable slit device 90a and the second variable slit device 90b have similar configurations to the variable slit device 90 according to the fourth modification.

The incident optical system 76a and the exit optical system 76b are arranged to have a common focal plane and the second rotation optical device 70b is positioned on the focal plane. The first rotation optical device 70a is arranged on the incident side of the incident optical system 76a. In the present modification, the optical element of the first rotation optical device 70a is referred to as a first optical element 71a, and the optical element of the second rotation optical device 70b is referred to as a second optical element 71b. The incident optical system 76a performs Fourier transform on an image of the pulse laser light PL to the position of the second optical element 71b. That is, in the example shown in FIG. 41, the second optical element 71b is arranged on the Fourier transform plane.

The first variable slit device 90a is arranged near the Fourier transform plane. The second variable slit device 90b is arranged on the output side of the exit optical system 76b. The position of the first rotation optical device 70a and the position of the second variable slit device 90b are in a conjugate positional relationship with each other. In the present modification, the first rotation optical device 70a is arranged near the output surface of the pulse laser light PL, and the second variable slit device 90b is arranged near the conjugate plane conjugate to the output surface.

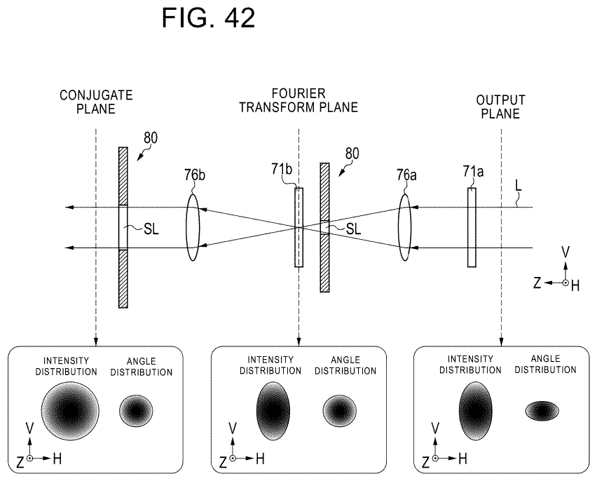

FIG. 42 shows an example of the beam angle distribution and the beam intensity distribution on each of the output plane, the Fourier transform plane, and the conjugate plane. In the present modification, the beam angle distribution is adjusted by the first optical element 71a and the beam intensity distribution is adjusted by the second optical element 71b.

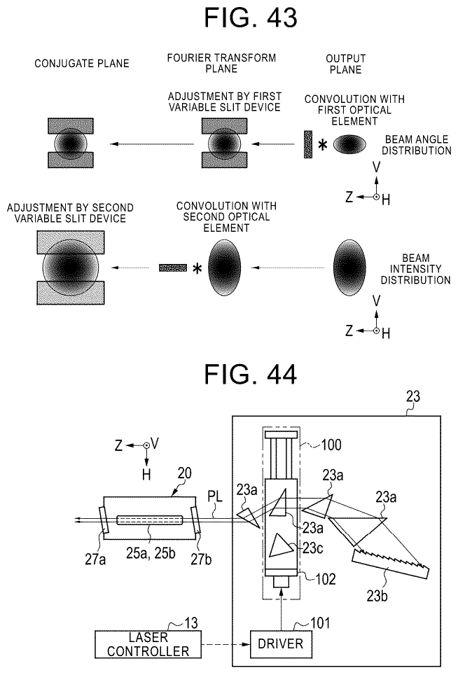

FIG. 43 shows an adjustment example of the beam angle distribution and the beam intensity distribution by the first variable slit device 90a and the second variable slit device 90b.

The first optical element 71a and the first variable slit device 90a are used to adjust the beam angle distribution. The beam angle distribution is adjusted by convolution with the first optical element 71a. Further, the beam angle distribution is adjusted by the slit SL of the first variable slit device 90a. The first optical element 71a allows adjustment in a direction of increasing the beam divergence angle Ω, and the first variable slit device 90a allows adjustment in a direction of decreasing the beam divergence angle Ω.

The second optical element 71b and the second variable slit device 90b are used to adjust the beam intensity distribution. The beam intensity distribution is adjusted by convolution with the second optical element 71b. Further, the beam intensity distribution is adjusted by the slit SL of the second variable slit device 90b. The second optical element 71b allows adjustment in a direction of increasing the beam cross-sectional area, and the second variable slit device 90b allows adjustment in a direction of decreasing the beam cross-sectional area.

In the present modification, the laser controller 13 performs following control to adjust the etendue ET. The laser controller 13 rotates the rotation holder 72 of the first rotation optical device 70a to select the first optical element 71a to be arranged on the optical path of the pulse laser light PL, thereby adjusting the beam angle distribution. Further, the laser controller 13 rotates the rotation holder 72 of the second rotation optical device 70b to select the second optical element 71b to be arranged on the optical path of the pulse laser light PL, thereby adjusting the beam intensity distribution.

Further, the laser controller 13 adjusts the beam angle distribution by adjusting the slit width of the first variable slit device 90a. Further, the laser controller 13 adjusts the beam intensity distribution by adjusting the slit width of the second variable slit device 90b.

In the present modification, since the beam divergence angle Ω and the beam cross-sectional area A can be adjusted in the increasing direction and the decreasing direction, respectively, the etendue ET can be adjusted with higher degree of freedom.

Here, the etendue ET may be adjusted through combination of two or more etendue changing devices among the plurality of etendue changing devices described in the third embodiment and the first to fifth modifications.

### 8. Modification of Spectral Line Width Changing Device

Next, various modifications of the spectral line width changing device will be described. Although the wavefront changing device 29 is used as the spectral line width changing device in the modification of the second embodiment and the third embodiment, the spectral line width changing device described below can be used instead of the wavefront changing device 29 or in addition to the wavefront changing device 29.

FIG. 44 schematically shows the configuration of the spectral line width changing device according to a modification. The spectral line width changing device according to the present modification is configured by adding a magnification changing mechanism 100 to the line narrowing device 23.

The line narrowing device 23 according to the present modification includes a plurality of prisms 23a, a grating 23b, the magnification changing mechanism 100, and a driver 101. For example, each of the plurality of prisms 23a is a right-angled prism. The plurality of prisms 23a cause the pulse laser light PL incident from the chamber 20 to be incident on the grating 23b with the beam width expanded. The plurality of prisms 23a cause the pulse laser light PL reflected by the grating 23b to enter the chamber 20 with the beam width reduced.

The magnification changing mechanism 100 is configured to be capable of changing the spectral line width E95 of the pulse laser light PL by changing one of the prisms 23a to a dispersion prism 23c. Specifically, the magnification changing mechanism 100 includes a movement stage 102 on which one prism 23a and a dispersion prism 23c are placed. As the movement stage 102 moves, the prism 23a or the dispersion prism 23c is selectively arranged on the optical path of the pulse laser light PL in the line narrowing device 23. The driver 101 drives the movement stage 102 based on control of the laser controller 13.

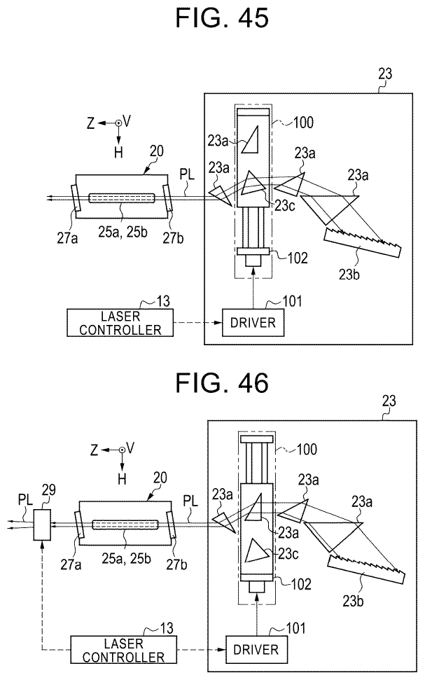

In the present modification, the laser controller 13 controls the movement stage 102 to change the spectral line width E95 by selectively arranging the prism 23a or the dispersion prism 23c on the optical path of the pulse laser light PL. As shown in FIG. 45, when the dispersion prism 23c is arranged on the optical path of the pulse laser light PL, the spectral line width E95 is increased than when the prism 23a is arranged.

In the present modification, the spectral line width E95 is changed by selectively arranging one of two prisms having different optical properties on the optical path of the pulse laser light PL in the line narrowing device 23. The spectral line width E95 may be changed by selectively arranging one of three prisms having different optical properties on the optical path. Thus, the adjustable range of the spectral line width E95 can be widened.

Further, as shown in FIG. 46, the line narrowing device 23 according to the present modification and the wavefront changing device 29 may be combined. In this case, the laser controller 13 controls the line narrowing device 23 and the wavefront changing device 29. For example, the laser controller 13 performs rough adjustment of the spectral line width E95 by the line narrowing device 23, and then performs fine adjustment of the spectral line width E95 by the wavefront changing device 29.

### 9. Electronic Device Manufacturing Method

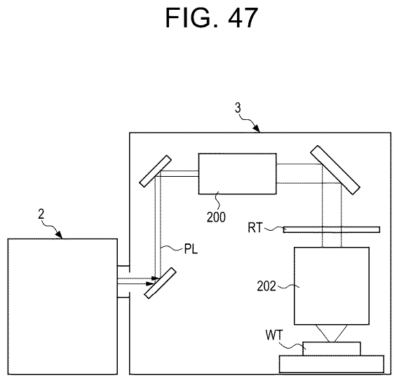

FIG. 47 schematically shows a configuration example of the exposure apparatus 3. The exposure apparatus 3 includes an illumination optical system 200 and a projection optical system 202. For example, the illumination optical system 200 illuminates a reticle pattern of a reticle (not shown) arranged on a reticle stage RT with the pulse laser light PL incident from the laser device 2. The projection optical system 202 causes the pulse laser light PL transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 3 synchronously translates the reticle stage RT and the workpiece table WT to expose the workpiece to the pulse laser light PL reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure.

### 10. Configuration Example of Laser Controller

In the present disclosure, the laser controller 13 can be realized by a combination of hardware and software of one or more computers. Software is synonymous with programs. A programmable controller is included in the concept of the computer. The computer may include a central processing unit (CPU) and a memory. The CPU included in the computer is an example of the processor.

Some or all of the functions of the laser controller 13 may be realized by using an integrated circuit such as a field programmable gate array (FPGA) or an application specific integrated circuit (ASIC).

The description above is intended to be illustrative and the present disclosure is not limited thereto. Therefore, it would be obvious to those skilled in the art that various modifications to the embodiments of the present disclosure would be possible without departing from the spirit and the scope of the appended claims.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A laser device comprising:
a laser oscillation device configured to output pulse laser light;
a beam intensity distribution measurement device configured to measure a beam intensity distribution of the pulse laser light;
a beam angle distribution measurement device configured to measure a beam angle distribution of the pulse laser light;
a pulse waveform measurement device configured to measure a pulse waveform of the pulse laser light;
a spectrum measurement device configured to measure a spectrum of the pulse laser light; and
a laser controller configured to calculate a speckle contrast based on measurement data of each of the beam intensity distribution, the beam angle distribution, the pulse waveform, and the spectrum.

2. The laser device according to claim 1,
wherein the laser controller calculates a pulse width from the pulse waveform, calculates an etendue from the beam intensity distribution and the beam angle distribution, calculates a spectral line width from the spectrum, and calculates the speckle contrast based on the pulse width, the etendue, and the spectral line width.

3. The laser device according to claim 2,
wherein the laser controller calculates the speckle contrast with the following expression (1), where the speckle contrast is SC, the pulse width is W, the etendue is ET, the spectral line width is Δλ, a wavelength of the pulse laser light is λ, a light velocity is c, and a pulse number of the pulse laser light is Nₚᵤₗₛₑ
$$[ Expression 1 ]$$
$$SC = \sqrt{\frac{1}{{N}_{pulse}}} \times \sqrt{\frac{1}{W} \cdot \frac{{λ}^{2}}{c \cdot Δλ} + \frac{{λ}^{2}}{ET}} . \qquad ( 1 )$$

4. The laser device according to claim 3,
wherein the pulse width is TIS and the spectral line width is E95.

5. The laser device according to claim 3,
wherein the pulse number is a number of pulses to be used by an exposure apparatus at the time of exposure, and the laser controller acquires the pulse number from the exposure apparatus.

6. The laser device according to claim 2,
wherein the laser controller calculates a beam cross-sectional area from the beam intensity distribution, calculates a beam divergence angle from the beam angle distribution, and calculates the etendue by multiplying the beam cross-sectional area by the beam divergence angle.

7. The laser device according to claim 1,
wherein the laser controller causes a display device to display the calculated speckle contrast.

8. The laser device according to claim 1,
wherein the beam intensity distribution measurement device includes a transfer optical system and an image sensor arranged at a position where a beam cross-sectional image of the pulse laser light is transferred by the transfer optical system.

9. The laser device according to claim 1,
wherein the beam angle distribution measurement device includes a light concentrating optical system and an image sensor arranged at a position where the pulse laser light is concentrated by the light concentrating optical system.

10. The laser device according to claim 1,
wherein the pulse waveform measurement device includes a diffusion plate, and a biplanar photoelectric tube arranged at a position where the pulse laser light diffused by the diffusion plate can be received.

11. The laser device according to claim 1,
wherein the spectrum measurement device is an etalon spectrometer.

12. The laser device according to claim 2,
further comprising one or more of devices among a pulse width changing device configured to change the pulse width, an etendue changing device configured to change the etendue, and a spectral line width changing device configured to change the spectral line width,
wherein the laser controller controls the one or more of devices so that the speckle contrast becomes equal to or less than a target value.

13. The laser device according to claim 2,
further comprising a pulse width changing device configured to change the pulse width, an etendue changing device configured to change the etendue, and a spectral line width changing device configured to change the spectral line width,
wherein the laser controller adjusts the pulse width, the etendue, and the spectral line width in this order so that the speckle contrast becomes equal to or less than a target value.

14. The laser device according to claim 12,
wherein the laser controller acquires the target value from an exposure apparatus.

15. The laser device according to claim 12,
wherein the oscillation device includes a chamber in which a laser gas is enclosed, and
the pulse width changing device changes the pulse width by controlling a concentration of a halogen gas or a concentration of an argon gas in the chamber.

16. The laser device according to claim 12,
further comprising an optical pulse stretcher arranged on an optical path of the pulse laser light,
wherein the pulse width changing device changes the pulse width by controlling a reflectance of a beam splitter or a transmittance of an ND filter arranged on a delay optical path of the optical pulse stretcher.

17. The laser device according to claim 12,
wherein the etendue changing device changes the etendue by controlling a posture of one or more of concave mirrors among a plurality of concave mirrors configuring an optical pulse stretcher to change a beam divergence angle.

18. The laser device according to claim 12,
wherein the etendue changing device changes the etendue by selectively arranging a plurality of optical elements having different optical properties on an optical path of the pulse laser light.

19. The laser device according to claim 12,
wherein the spectral line width changing device is configured by a wavefront changing device configured to change a wavefront of the pulse laser light, a line narrowing device configured to line-narrow the pulse laser light, or a combination of the wavefront changing device and the line narrowing device.

20. An electronic device manufacturing method, comprising:
outputting pulse laser light from a laser device to an exposure apparatus; and
exposing a photosensitive substrate to the pulse laser light in the exposure apparatus to manufacture an electronic device,
the laser device including:
a laser oscillation device configured to output the pulse laser light;
a beam intensity distribution measurement device configured to measure a beam intensity distribution of the pulse laser light;
a beam angle distribution measurement device configured to measure a beam angle distribution of the pulse laser light;
a pulse waveform measurement device configured to measure a pulse waveform of the pulse laser light;
a spectrum measurement device configured to measure a spectrum of the pulse laser light; and
a laser controller configured to calculate a speckle contrast based on measurement data of each of the beam intensity distribution, the beam angle distribution, the pulse waveform, and the spectrum.
